(19) United States
(12) Patent Application Publication
(10) Pub. No.: US 2019/0348213 A1
(43) Pub. Date: Nov. 14, 2019

(54) PLANAR TRANSFORMER, LASER DIODE-DRIVING POWER SUPPLY, AND LASER MACHINING APPARATUS

(71) Applicant: Mitsubishi Electric Corporation, Tokyo (JP)

(72) Inventors: Hiroshi IKARASHI, Tokyo (JP); Yoshikazu TSUNODA, Tokyo (JP); Akihiko IWATA, Tokyo (JP); Takeshi MORIMOTO, Tokyo (JP)

(73) Assignee: Mitsubishi Electric Corporation, Tokyo (JP)

(21) Appl. No.: 16/349,622

(22) PCT Filed: Apr. 17, 2017
(86) PCT No.: PCT/JP2017/015484

§ 371 Date: May 14, 2019

(51) Int. Cl. H01F 27/28; H01F 27/24; H01F 27/32; H01S 5/042; H01F 30/06; H02M 3/335; H02M 7/06; B23K 26/00

(52) U.S. Cl. CPC H01F 27/2847; H01F 27/24; H01F 27/321; B23K 26/00; H01F 30/06; H02M 3/33569; H02M 7/06; H01S 5/042

(57) ABSTRACT

A planar transformer includes a plurality of EI cores, a primary winding board provided with primary windings each surrounding a corresponding one of the EI cores, a first secondary winding board provided with secondary windings each surrounding a corresponding one of the EI cores, and a second secondary winding board provided with secondary windings each surrounding a corresponding one of the EI cores. The primary winding board, the first secondary winding board, and the second secondary winding board are layered in a spaced relation to each other.

### FIELD

The present invention relates to a planar transformer with cores, a laser diode-driving power supply, and a laser machining apparatus.

### BACKGROUND

A transformer of a flat structure disclosed in Patent Literature 1 includes a printed circuit board having recessed portions formed therein, and magnetic cores disposed in the recessed portions. Primary windings and secondary windings are provided around the recessed portions formed in the printed circuit board. For the flat-structure transformer disclosed in Patent Literature 1, the primary windings and the secondary windings, which are provided on the single printed circuit board, are electrically isolated from each other. Protruding portions of the magnetic cores are inserted in the recessed portions of the printed circuit board. For the flat-structure transformer disclosed in Patent Literature 1, a desired transformer ratio is set by changing the turns ratio between the primary windings and the secondary windings.

### CITATION LIST

### Patent Literature

Patent Literature 1: Japanese Patent Application Laid-open No. 2007-88131

### SUMMARY

### Technical Problem

The AC resistance of a winding against high-frequency components increases as the frequency increases, due to skin effect caused by the flow of alternating current through a conductor and proximity effect occurring between adjacent conductors. Thus, the higher the frequency, the less the current flows through the winding. The higher the power and the current becomes, the more noticeable this phenomenon is. For a transformer for high-power applications, when the width of a wiring pattern that defines a winding is increased to provide against the heat generation of the winding, the number of turns is relatively decreased. As a result, it is difficult to obtain magnetizing inductance of a certain value to the extent possible without magnetic saturation of the core. For the flat-structure transformer disclosed in Patent Literature 1, the primary windings are provided on one plate surface of the single board and the secondary windings are provided on the other plate surface, so that the winding length can be increased, and magnetizing inductance of a certain value can be obtained. Unfortunately, due to the primary windings and the secondary windings being provided on the single board, the distance between adjacent conductors is small. Thus, in high-power and high-current applications, the windings are affected by skin effect and proximity effect, resulting in the problem of increased loss.

The present invention has been made in view of the above, and an object thereof is to provide a planar transformer capable of being used in high-power and high-current applications.

### Solution to Problem

To solve the above problem and achieve the object, the present invention provides A planar transformer comprising: a plurality of cores; a primary winding board provided with primary windings each surrounding a corresponding one of the cores; and a secondary winding board provided with secondary windings each surrounding the corresponding one of the cores, wherein the primary winding board and the secondary winding board are layered in a spaced relation with each other.

### Advantageous Effects of Invention

The planar transformer according to the present invention has an advantage of being able to be used in high-power and high-current applications.

### BRIEF DESCRIPTION OF DRAWINGS

FIG. 1 is a configuration diagram of a laser machining apparatus according to the present embodiment.

FIG. 2 is a diagram illustrating a configuration example of a laser diode-driving power supply according to the present embodiment.

FIG. 3 is a first perspective view of a planar transformer according to the present embodiment.

FIG. 4 is a second perspective view of the planar transformer according to the present embodiment.

FIG. 5 is a cross-sectional view of the planar transformer illustrated in FIG. 3.

FIG. 6 is a partial enlarged view of the planar transformer illustrated in FIGS. 3 and 4.

FIG. 7 is a diagram illustrating a first modification of the planar transformer according to the present embodiment.

FIG. 8 is a partial enlarged view of the planar transformer illustrated in FIG. 7.

FIG. 9 is a diagram illustrating a first modification of the laser diode-driving power supply according to the present embodiment.

FIG. 10 is a diagram illustrating a second modification of the laser diode-driving power supply according to the present embodiment.

FIG. 11 is a diagram illustrating a modification of windings illustrated in FIG. 5.

### DESCRIPTION OF EMBODIMENT

Hereinafter, a planar transformer, a laser diode-driving power supply, and a laser machining apparatus according to an embodiment of the present invention will be described in detail with reference to the drawings. Note that the embodiment is not intended to limit the invention.

### EMBODIMENT

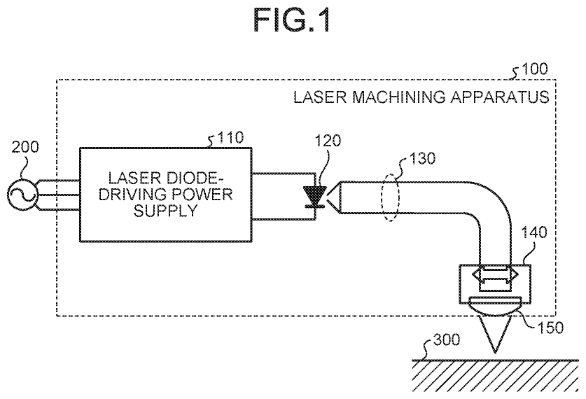

FIG. 1 is a configuration diagram of a laser machining apparatus according to the present embodiment. A laser machining apparatus 100 illustrated in FIG. 1 includes a laser diode-driving power supply 110 that converts AC voltage supplied from a three-phase or single-phase AC source 200 into DC voltage, and a laser diode 120 that emits a laser by direct current supplied from the laser diode-driving power supply 110. The apparatus 100 further includes a fiber 130, a machining head 140 for machining a workpiece 300, and a lens 150.

The fiber 130 includes an optical coupling system and an optical amplifier for transmitting a laser emitted from the laser diode 120 by the machining head 140. A laser output from the laser diode 120 is transmitted to the machining head 140 by the fiber 130, and is focused on the workpiece 300 by the lens 150 in the machining head 140, thereby cutting the workpiece 300. During machining of the workpiece 300, it is necessary to move the laser focus position on the workpiece 300. For this reason, the workpiece 300 is placed on a workpiece moving mechanism (not illustrated) for moving the workpiece 300, or a head moving mechanism (not illustrated) for moving the machining head 140 is provided to the laser machining apparatus 100.

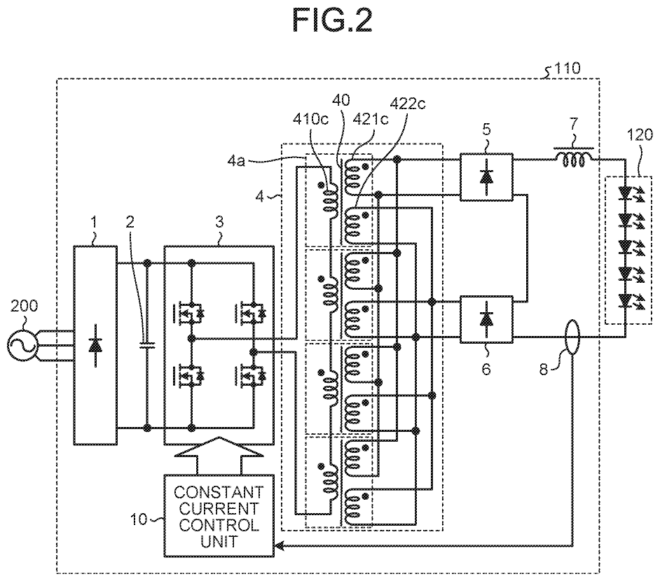

FIG. 2 is a diagram illustrating a configuration example of the laser diode-driving power supply according to the present embodiment. The laser diode-driving power supply 110 is a constant current-mode isolated-type power converter controlled by a constant current control unit 10. The constant current control unit 10 controls a plurality of switching elements included in an inverter circuit 3, on the basis of current detected by a current detector 8 that detects current flowing through the laser diode 120.

The laser diode-driving power supply 110 includes a rectifier circuit 1 that rectifies AC voltage supplied from the AC source 200, a capacitor 2 connected in parallel to the rectifier circuit 1, the inverter circuit 3, a planar transformer 4, two rectifier diodes 5 and 6, and a smoothing reactor 7.

The planar transformer 4 is made up of four transformers 4a. Each of the four transformers 4a includes an EI core group 40, a primary winding 410c, a plurality of secondary windings 421c, and a plurality of secondary windings 422c. The primary winding 410c is electrically connected to output ends of the inverter circuit 3. The plurality of secondary windings 421c, which are first secondary windings, are electrically connected to the rectifier diode 5. The plurality of secondary windings 422c, which are second secondary windings, are electrically connected to the rectifier diode 6.

The EI core group 40 of each of the four transformers 4a is formed by a combination of an E core of an “E” shape and an I core of an “I” shape. Each of the plurality of primary windings 410c, secondary windings 421c, and secondary windings 422c is formed by a wiring pattern on a board, and is provided to surround the peripheries of the E cores. The primary windings 410c and the secondary windings 421c are electromagnetically inductively coupled by the E cores and the I cores, and the primary windings 410c and the secondary windings 422c are electromagnetically inductively coupled by the E cores and the I cores.

The primary windings 410c included in the four transformers 4a are connected in series. The secondary windings 421c included in the four transformers 4a are connected in parallel. The secondary windings 422c included in the four transformers 4a are connected in parallel.

The planar transformer 4 is provided with two secondary-side outputs. One of the two secondary-side outputs is both ends of the plurality of secondary windings 421c connected in parallel, and is connected to the rectifier diode 5. The other secondary-side output is both ends of the plurality of secondary windings 422c connected in parallel, and is connected to the rectifier diode 6.

DC voltage rectified by the rectifier circuit 1 is converted by the inverter circuit 3 into a high frequency voltage of some tens of kHz to some hundreds of kHz. The high frequency voltage converted by the inverter circuit 3 is input to the primary side of the planar transformer 4, and is boosted or reduced by the planar transformer 4.

Current output from the secondary side of the planar transformer 4 flows through the rectifier diodes 5 and 6 and the smoothing reactor 7 to the laser diode 120. The rectifier diodes 5 and 6 and the smoothing reactor 7 reduce ripple current of current input to the laser diode 120.

The output voltage of the laser diode-driving power supply 110 thus configured is adjusted by the turns ratio of the planar transformer 4. The output current of the laser diode-driving power supply 110 is adjusted by the ratio of on-time to the switching period of the plurality of switching elements in the inverter circuit 3.

In the laser diode-driving power supply 110, DC voltage rectified by the rectifier circuit 1 is applied to the inverter circuit 3. Alternatively, a Power Factor Correction (PFC) circuit for improving the power factor may be provided between the rectifier circuit 1 and the inverter circuit 3 so that DC voltage rectified by the rectifier circuit 1 is boosted to a certain voltage by the PFC circuit, and the boosted voltage is applied to the inverter circuit 3.

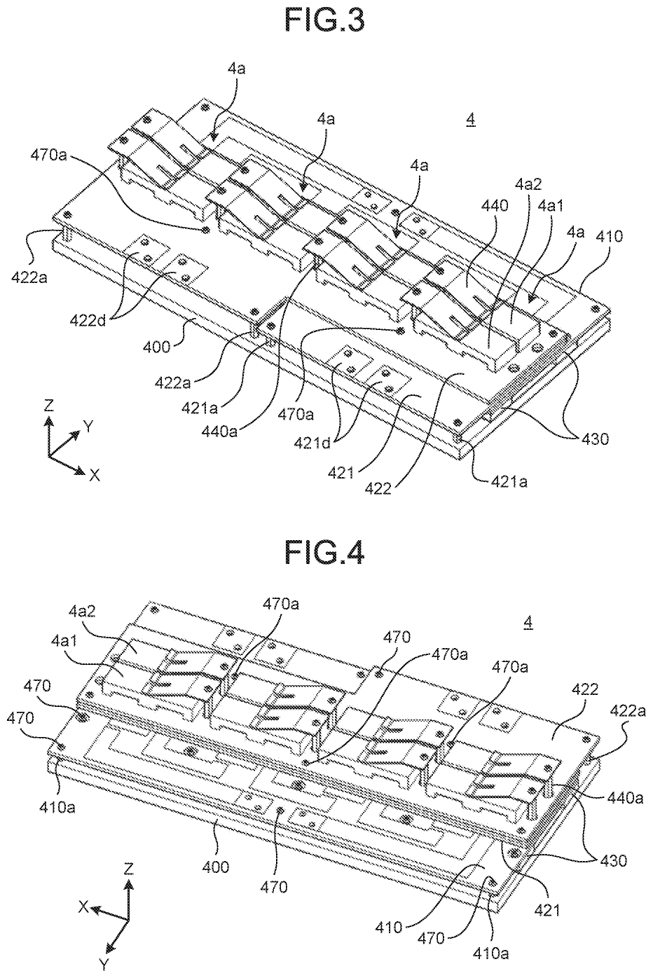

FIG. 3 is a first perspective view of the planar transformer according to the present embodiment. FIG. 4 is a second perspective view of the planar transformer according to the present embodiment. In a right-handed XYZ coordinate system in FIGS. 3 and 4, the direction of arrangement of the plurality of transformers 4a is the X-axis direction, a direction orthogonal to the X-axis direction is the Y-axis direction, and a direction orthogonal to both the X-axis direction and the Y-axis direction is the Z-axis direction.

The planar transformer 4 includes a metal plate 400, a primary winding board 410, a first secondary winding board 421, a second secondary winding board 422, which are arranged in the Z-axis direction, and the four transformers 4a.

The planar transformer 4 also includes spacers 410a, spacers 421a, spacers 422a, auxiliary plates 430, pressing springs 440, and spacers 440a. The spacers 410a serve as fixing members for fixing the primary winding board 410 to the metal plate 400. The spacers 421a serve as fixing members for fixing the first secondary winding board 421 to the metal plate 400. The spacers 422a serve as fixing members for fixing the second secondary winding board 422 to the metal plate 400. The auxiliary plates 430 are provided between the primary winding board 410 and the metal plate 400. The spacers 440a serve as spring fixing members for fixing the pressing springs 440 to the metal plate 400.

The materials of the metal plate 400 and the auxiliary plates 430 can be exemplified by an aluminum alloy, an austenitic stainless alloy, a copper alloy, cast iron, steel, or an iron alloy.

One transformer 4a is composed of a pair of two cores: an EI core 4a1; and an EI core 4a2. The pair of the EI core 4a1 and the EI core 4a2 corresponds to the single EI core group 40 illustrated in FIG. 2.

One end of the spacer 410a in the Z-axis direction is screwed to the metal plate 400, and the other end of the spacer 410a in the Z-axis direction is screwed to the primary winding board 410. One end of the spacer 421a in the Z-axis direction is screwed to the metal plate 400, and the other end of the spacer 421a in the Z-axis direction is screwed to the first secondary winding board 421. One end of the spacer 422a in the Z-axis direction is screwed to the metal plate 400, and the other end of the spacer 422a in the Z-axis direction is screwed to the second secondary winding board 422. The spacer 410a, the spacer 421a, and the spacer 422a have their lengths in the Z-axis direction that have a relationship: the spacer 410a<the spacer 421a<the spacer 422a.

A pair of output terminals 421d, which define first output terminals, are provided on the first secondary winding board 421. The pair of output terminals 421d are connected to both ends of the secondary windings 421c by a wiring pattern (not illustrated) provided on the first secondary winding board 421.

A pair of output terminals 422d, which define second output terminals, are provided on the second secondary winding board 422. The pair of output terminals 422d are connected to both ends of the secondary windings 422c by a wiring pattern (not illustrated) provided on the second secondary winding board 422.

The pair of output terminals 421d are connected to the rectifier diode 5 illustrated in FIG. 2 via electric wires or a bus bar (not illustrated). The pair of output terminals 422d are connected to the rectifier diode 6 illustrated in FIG. 2 via electric wires or a bus bar (not illustrated). When the first secondary winding board 421 is viewed from the second secondary winding board 422 in the Z-axis direction, the position of the pair of output terminals 421d on an X-Y plane is different from the position of the pair of output terminals 422d on an X-Y plane. Providing the pair of output terminals 421d and the pair of output terminals 422d at the different positions facilitates connection of electric wires or bus bars to the output terminals.

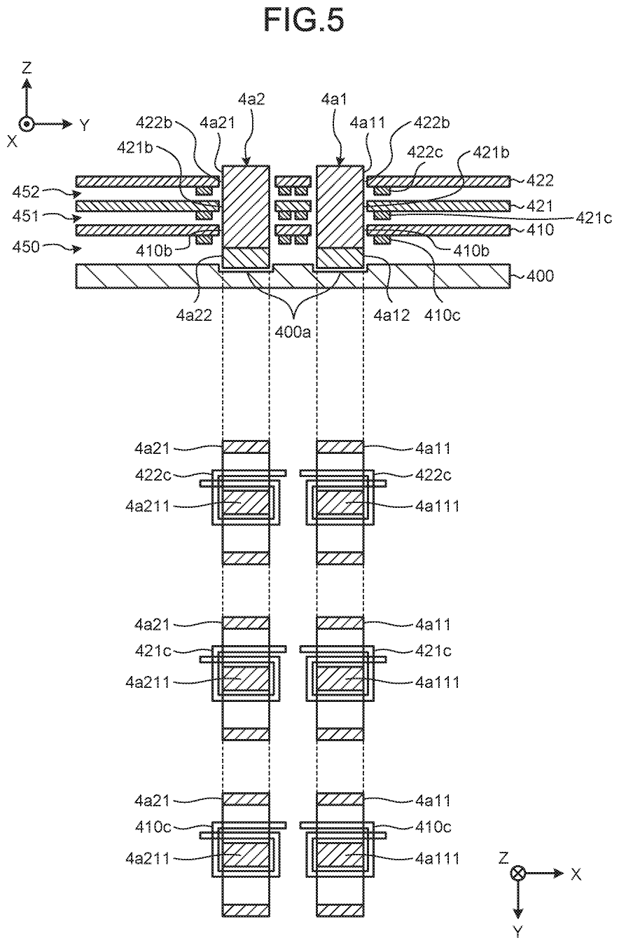

FIG. 5 is a cross-sectional view of the planar transformer illustrated in FIG. 3. For convenience of explanation, the spacing widths between the metal plate 400, the primary winding board 410, the first secondary winding board 421, and the second secondary winding board 422 illustrated in FIG. 5 are larger than the spacing widths between them illustrated in FIG. 3. The same applies to the spacing width between the EI core 4a1 and the EI core 4a2. Illustrated on the upper side of FIG. 5 is a cross-sectional view of the planar transformer 4 as viewed on a Y-Z plane. Illustrated on the lower side of FIG. 5 is the state of the winding on the primary winding board 410, the first secondary winding board 421, and the second secondary winding board 422 as viewed in the Z-axis direction is illustrated.

Specifically, on the lower side of FIG. 5, there are illustrated a center leg 4a111 provided at the E core 4a11, the primary winding 410c wound around the center leg 4a111, the secondary winding 421c wound around the center leg 4a111, and the secondary winding 422c wound around the center leg 4a111. Also, on the lower side of FIG. 5, there are illustrated a center leg 4a211 provided at the E core 4a21, the primary winding 410c wound around the center leg 4a211, the secondary winding 421c wound around the center leg 4a211, and the secondary winding 422c wound around the center leg 4a211.

The metal plate 400, the primary winding board 410, the first secondary winding board 421, and the second secondary winding board 422 are spaced apart from each other in the Z-axis direction. A gap 450 is formed between the primary winding board 410 and the metal plate 400. A gap 451 is formed between the primary winding board 410 and the first secondary winding board 421. A gap 452 is formed between the first secondary winding board 421 and the second secondary winding board 422. The widths of these gaps are adjusted by changing the lengths of the spacers 410a, the spacers 421a, and the spacers 422a illustrated in FIGS. 3 and 4.

The primary winding board 410 has a plurality of through holes 410b formed therethrough in the Z-axis direction, and is provided with the primary windings 410c. The primary windings 410c are provided on the primary winding board 410 and surround the through holes 410b.

The first secondary winding board 421 has a plurality of through holes 421b formed therethrough in the Z-axis direction, and is provided with the secondary windings 421c. The secondary windings 421c are provided on the first secondary winding board 421 and surround the through holes 421b.

The second secondary winding board 422 has a plurality of through holes 422b formed therethrough in the Z-axis direction, and is provided with the secondary windings 422c. The secondary windings 422c are provided on the second secondary winding board 422 and surround the through holes 422b.

The primary windings 410c, the secondary windings 421c, and the secondary windings 422c are formed as planar coil patterns by patterning conductive films.

The through holes 410b, the through holes 421b, and the through holes 422b are aligned in the Z-axis direction. The E cores 4a11 of the EI cores 4a1 and the E cores 4a21 of the EI cores 4a2 are inserted through the through holes.

I cores 4a12 of the EI cores 4a1 are connected to distal end portions of the E cores 4a11 in the Z-axis direction. I cores 4a22 of the EI cores 4a2 are connected to distal end portions of the E cores 4a21 in the Z-axis direction.

The I cores 4a12 and the I cores 4a22 are provided in the gap 450. The metal plate 400 has recessed portions 400a formed in an end face thereof in the X-axis direction. The recessed portions 400a are fitting portions for positioning the I cores 4a12 and the I cores 4a22 on an X-Y plane.

The primary winding 410c, the secondary winding 421c, and the secondary winding 422c illustrated in FIG. 5 are provided in association with each of the four pairs of the EI core 4a1 and the EI core 4a2 illustrated in FIGS. 3 and 4.

The primary windings 410c associated with the pairs of the EI cores 4a1 and the EI cores 4a2 are connected in series. Both ends of the primary winding group connected in series, which serve as input ends of the planar transformer 4 illustrated in FIG. 2, are connected to the inverter circuit 3.

The secondary windings 421c associated with the pairs of the EI cores 4a1 and the EI cores 4a2 are connected in parallel. Both ends of each of the plurality of secondary windings 421c connected in parallel, which serve as output ends of the planar transformer 4 illustrated in FIG. 2, are connected to the rectifier diode 5.

The secondary windings 422c associated with the pairs of the EI cores 4a1 and the EI cores 4a2 are connected in parallel. Both ends of each of the plurality of secondary windings 422c connected in parallel, which serve as output ends of the planar transformer 4 illustrated in FIG. 2, are connected to the rectifier diode 6.

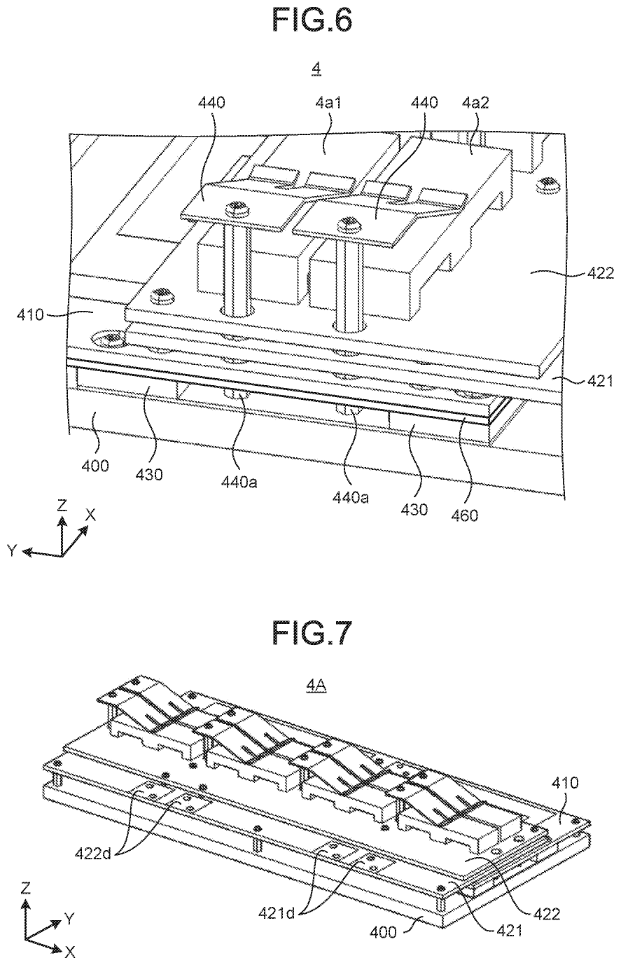

FIG. 6 is a partial enlarged view of the planar transformer illustrated in FIGS. 3 and 4. As illustrated in FIG. 6, the EI cores 4a1 and the EI cores 4a2 are provided between the two auxiliary plates 430 arranged in the Y-axis direction. A pair of the I core 4a12 and the I core 4a22 illustrated in FIG. 5 are provided between the two auxiliary plates 430 illustrated in FIG. 6.

The auxiliary plates 430 and an insulating sheet 460 are provided between the primary winding board 410 and the metal plate 400. The auxiliary plates 430 and the insulating sheet 460 are arranged in the Z-axis direction and screwed to each other. The insulating sheet 460 is provided between the auxiliary plates 430 and the primary winding board 410.

The insulating sheet 460 is a sheet having an insulating property and high thermal conductivity. Specifically, the insulating sheet 460 is a member produced by mixing particles having high thermal conductivity or powder having high thermal conductivity into a sheet having an insulating property. The material of the sheet having the insulating property can be exemplified by silicone rubber, polyisobutylene rubber, or acrylic rubber. The material of the particles having high thermal conductivity or the powder having high thermal conductivity can be exemplified by aluminum oxide, aluminum nitride, zinc oxide, silica, or mica.

The EI cores 4a1 and the EI cores 4a2 are fixed by the pressing springs 440. The spacers 440a for fixing the pressing springs 440 are inserted into through holes formed in the primary winding board 410, the first secondary winding board 421, and the second secondary winding board 422, and screwed to the metal plate 400. Consequently, the pressing springs 440 urge the EI cores 4a1 and the EI cores 4a2 toward the metal plate 400.

As described above, in the laser diode-driving power supply 110 according to the present embodiment, the primary windings 410c, the secondary windings 421c, and the secondary windings 422c are formed on the different boards. Consequently, the pattern width of each of the wiring patterns defined by the primary windings 410c, the secondary windings 421c, and the secondary windings 422c can be widened close to the width of openings formed for the EI core groups 40, maintaining a certain insulating distance. Thus, an increase in the resistance value due to the narrowing of the wiring patterns can be prevented.

Since the primary winding board 410 and the first secondary winding board 421 are held with the gap 451 therebetween, a large leakage inductance is obtained in the planar transformer 4. This leakage inductance is used as resonant inductance for the Zero-Voltage Switching (ZVS) control of the inverter circuit 3, thereby eliminates the need for an external resonant inductance becomes unnecessary, or enabling an external resonant inductance to be set to a low inductance value.

In the laser diode-driving power supply 110 according to the present embodiment, the primary windings 410c provided in the respective plurality of transformers 4a are connected in series. Therefore, even when the number of turns of the primary windings 410c per transformer 4a is small, a certain magnetizing inductance can be obtained by increasing the number of the transformers 4a in series.

Since the single planar transformer 4 is formed by using the plurality of transformers 4a, heat generated in the plurality of transformers 4a is dispersed, the areas of the windings are increased, and the heat dissipation areas of the cores are increased. Consequently, the temperature rise of the entire planar transformer 4 can be reduced.

For a transformer structure of a conventional art in which windings are wound around a plurality of protruding portions formed at a core, the core is large. For the large core, cracking is likely to occur during core sintering, resulting in a decrease in yield. To mechanically hold and fix the large core, a holding mechanism is complicated, and further, the holding mechanism needs to have a rigid structure. Consequently, there is a problem of an increase in the manufacturing cost of the transformer.

The planar transformer 4 according to the present embodiment can use general-purpose small EI cores. For the small EI cores, cracking during core sintering occurs less, and a decrease in yield is prevented. Consequently, the manufacturing cost of the planar transformer 4 can be reduced.

In the planar transformer 4 according to the present embodiment, the size of one transformer 4a is small. Thus, the cores can be mechanically held by a simple holding structure like the above-described pressing springs 440.

In the planar transformer 4 according to the present embodiment, the two secondary-side outputs are provided, and voltages output from the secondary-side outputs are rectified by the rectifier diodes 5 and 6 and then added up. Thus, a high voltage can be obtained without significantly changing the turns ratio of the transformers.

In the planar transformer 4 according to the present embodiment, voltages output from the secondary-side outputs are rectified by the rectifier diodes 5 and 6 and then added up. Thus, the withstand voltage of the rectifier diodes 5 and 6 can be reduced to a value calculated by “1/the number of the planer transformer outputs”. A diode with a high withstand voltage, which provide, for example, a large forward voltage and a long reverse recovery time, has not only poor electrical characteristics but also large power loss. The planar transformer 4 according to the present embodiment allows the use of the rectifier diodes 5 and 6 with a low withstand voltage, thus eliminating the problem of failure of secure the withstand voltage of the rectifier diodes 5 and 6, and also eliminates the problems of poor switching characteristics and large loss.

In the planar transformer 4 according to the present embodiment, the primary winding board 410 is thermally connected to the metal plate 400 via the insulating sheet 460 and the auxiliary plates 430, so that the primary windings 410c provided on the primary winding board 410 have improved heat dispersion characteristics, and a large current can be passed through the primary windings 410c. Generally, the value of current that can be passed through a wiring pattern on a board is rate-determined by the glass-transition temperature [Tg] of the board material. If the temperature rise of the wiring pattern can be limited to reduce the temperature of the board to less than the glass-transition temperature [Tg], a large current can be passed through the wiring pattern.

In the present embodiment, the primary winding board 410 is thermally connected to the metal plate 400 via the insulating sheet 460 and the auxiliary plates 430. Alternatively, at least one of the first secondary winding board 421 and the second secondary winding board 422 may be thermally connected to the metal plate 400 via the insulating sheet 460 and the auxiliary plates 430.

In the planar transformer 4 according to the present embodiment, as illustrated in FIG. 4, each of the boards is mechanically connected to the metal plate 400 by two or more screws 470. In FIG. 4, three or more screws 470 for fixing the primary winding board 410 are arranged in the X-axis direction. Likewise, three or more screws 470 for fixing the first secondary winding board 421 and the second secondary winding board 422 are arranged in the X-axis direction. In the planar transformer 4, as illustrated in FIGS. 3 and 4, a screw 470a is provided between two adjacent ones of the plurality of transformers 4a aligned in the X-axis direction. Like the screws 470, the screws 470a are fastening members for mechanically connecting the boards to the metal plate 400. In FIGS. 3 and 4, each screw 470a is provided near a gap between two adjacent transformers 4a. Note that three screws 470a are provided in FIGS. 3 and 4, but the number of the screws 470a is not limited to three and may be one or more. The provision of the screws 470a in this manner prevents the mechanical warpage of the boards, thus preventing corona discharge that occurs in an air layer between the primary winding board 410 and the metal plate 400 when mechanical warpage occurs in the boards, and preventing an increase in contact thermal resistance. To explain the prevention of contact thermal resistance specifically, as illustrated in FIG. 6, heat generated in the primary windings 410 of the plurality of transformers 4a is transmitted to the insulating sheet 460 and the auxiliary plates 430 in this order. The above-mentioned contact thermal resistance is the thermal resistance from the primary windings 410 to the insulating sheet 460 or the thermal resistance from the insulating sheet 460 to the auxiliary plates 430. If mechanical warpage occurs in the boards, an air layer is produced in the conduction path of heat generated in the primary windings 410. Due to this air layer, the contact thermal resistance is increased, thereby reducing the cooling effect of the primary windings 410. The planar transformer 4 according to the present embodiment prevents the mechanical warpage of the boards, thus preventing an increase in the contact thermal resistance and improving the cooling effect of the primary windings 410.

A conventional flat-structure transformer typified by Patent Literature 1 needs to use a multilayer board as the printed circuit board to obtain a desired magnetizing inductance in a high-power application of some kW or more. That is, a flat-structure transformer for high-power applications has the increased number of the board layers for the purpose of lowering the resistance value of the windings. Unfortunately, the multilayer board not only requires a high manufacturing cost, as compared to a single-layer board, but also has poor heat dissipation characteristics of inner-layer patterns. In the planar transformer 4 according to the present embodiment, the primary windings 410c provided to the plurality of transformers 4a are connected in series. Thus, by increasing the number of the transformers 4a in series, the turns ratio of the transformers 4a can be reduced to “1/the number in series”. Consequently, the number of turns of the windings on the plurality of transformers 4a is reduced and the number of board layers is reduced, improving the heat dissipation characteristics of the inner-layer patterns.

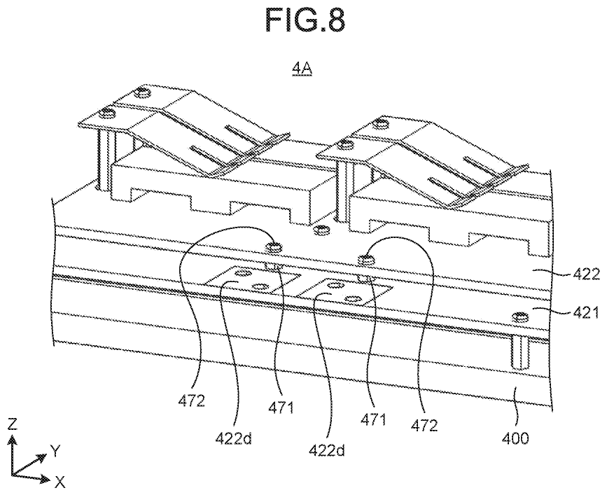

FIG. 7 is a diagram illustrating a first modification of the planar transformer according to the present embodiment. FIG. 8 is a partial enlarged view of the planar transformer illustrated in FIG. 7. In a planar transformer 4A illustrated in FIG. 7, the pair of output terminals 421d and the pair of output terminals 422d are provided on the first secondary winding board 421. Thus, the pair of output terminals 421d and the pair of output terminals 422d are at the same position in the Z-axis direction.

Each of the pair of output terminals 421d and the pair of output terminals 422d is provided near one end of the first secondary winding board 421 in the Y-axis direction. The pair of output terminals 421d is provided near one end of the first secondary winding board 421 in the X-axis direction. The pair of output terminals 422d is provided near the other end of the first secondary winding board 421 in the X-axis direction.

As illustrated in FIG. 8, the planar transformer 4A includes metal spacers 471 serving as conductive members disposed between the second secondary winding board 422 and the first secondary winding board 421. The planer transformer 4A also includes screws 472 for fixing the metal spacers 471. The material of the metal spacers 471 can be exemplified by a copper alloy, cast iron, steel, or an iron alloy.

One end of each metal spacer 471 in the Z-axis direction is connected to the wiring pattern (not illustrated) provided on the second secondary winding board 422. Thus, the metal spacers 471 are electrically connected to both ends of the secondary windings provided on the second secondary winding board 422.

The other end of each metal spacer 471 in the Z-axis direction is connected to the wiring pattern (not illustrated) provided on the first secondary winding board 421. Thus, the metal spacers 471 are electrically connected to the pair of output terminals 421d illustrated in FIG. 7.

In the planar transformer 4 illustrated in FIG. 3, the pair of output terminals 421d and the pair of output terminals 422d are at the different positions in the Z-axis direction. Consequently, in the work of connecting electric wires or bus bars to the rectifier diode 5 and the rectifier diode 6, electric wires or bus bars having different lengths and shapes are required. Therefore, the manufacturing cost of the bus bars is higher and the time required for the connecting work is longer than when electric wires or bus bars having the same length and shape are used.

The planar transformer 4A illustrated in FIG. 7 can use electric wires or bus bars having the same length and shape since the pair of output terminals 421d and the pair of output terminals 422d are at the same position in the Z-axis direction. When the rectifier diodes 5 and 6 are semiconductor modules, the rectifier diode 5 can be screwed to the pair of output terminals 421d, and the rectifier diode 6 can be screwed to the pair of output terminals 422d without using electric wires or bus bars.

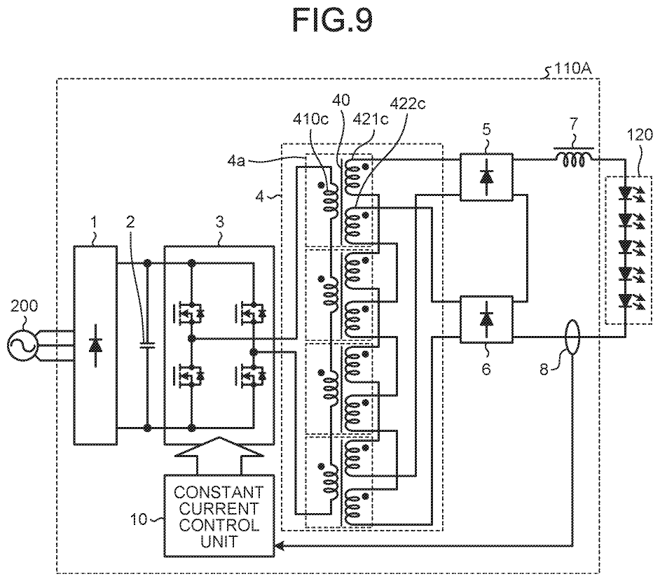

FIG. 9 is a diagram illustrating a first modification of the laser diode-driving power supply according to the present embodiment. In the laser diode-driving power supply 110 illustrated in FIG. 2, the four secondary windings 421c are connected in parallel, and the four secondary windings 422c are connected in parallel. In contrast to this, in a laser diode-driving power supply 110A illustrated in FIG. 9, the four secondary windings 421c are connected in series, and the four secondary windings 422c are connected in series.

Both ends of the plurality of secondary windings 421c connected in series form one secondary-side output, and both ends of the plurality of secondary windings 422c connected in series form the other secondary-side output.

The laser diode-driving power supply 110A is suitable for obtaining high voltage in the planar transformer 4 even when AC voltage input to the planar transformer 4 has a low value. The laser diode-driving power supply 110A can reduce the number of turns of the secondary windings per transformer 4a to “1/(the number of the outputs×the number of the transformers 4a)”. With the number of turns of the secondary windings being reduced, the pattern width of the secondary windings is increased and the winding resistance is reduced, thereby reducing loss due to copper loss.

In the laser diode-driving power supply 110A in FIG. 9, the primary windings 410c included in the four transformers 4a are connected in series. When a certain magnetizing inductance is obtained even with the primary windings 410c connected in parallel, the primary windings 410c are connected in parallel, thereby increasing the turns ratio per transformer 4a and obtaining high voltage even when AC voltage input to the planar transformer 4 has a low value.

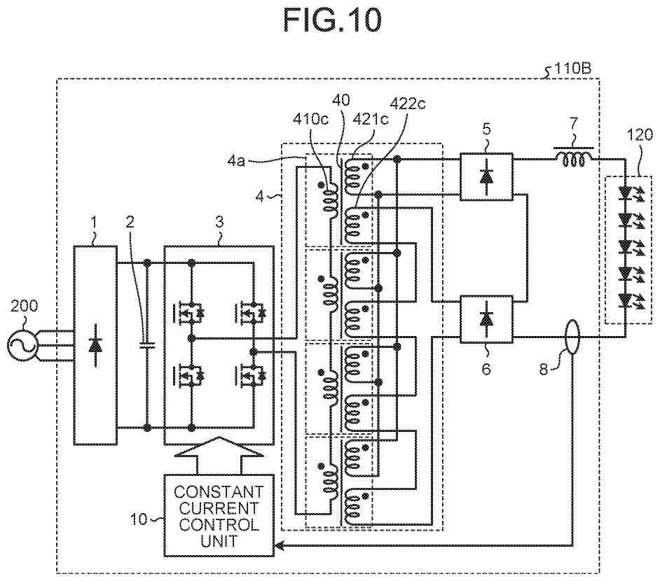

FIG. 10 is a diagram illustrating a second modification of the laser diode-driving power supply according to the present embodiment. In the laser diode-driving power supply 110 illustrated in FIG. 2, the four secondary windings 422c are connected in parallel. In contrast to this, in a laser diode-driving power supply 110B illustrated in FIG. 10, the four secondary windings 422c are connected in series. The laser diode-driving power supply 110B provides the same effects as the laser diode-driving power supply 110A illustrated in FIG. 9.

Although the planar transformer 4 according to the present embodiment has the two secondary-side outputs, the number of the secondary-side outputs of the planar transformer 4 is not limited to two, and may be two or more to provide the same effects as described above.

The present embodiment uses the first secondary winding board 421 and the second secondary winding board 422. In place of the first secondary winding board 421 and the second secondary winding board 422, a single secondary winding board on which the secondary windings 421c and the secondary windings 422c are provided may be used to provide the same effects. It is noted that when the first secondary winding board 421 and the second secondary winding board 422 are used, the first secondary winding board 421 and the second secondary winding board 422 can be spaced, so that heat generated in the secondary windings is radiated into the air, resulting in improved heat dissipation characteristics of the secondary windings.

In the present embodiment, as illustrated in FIG. 7, the pair of output terminals 421d and the pair of output terminals 422d are provided on the first secondary winding board 421. Alternatively, the pair of output terminals 421d and the pair of output terminals 422d may be provided on the second secondary winding board 422.

In the present embodiment, as illustrated in FIG. 6, the insulating sheet 460 and the auxiliary plates 430 are provided between the primary winding board 410 and the metal plate 400. However, the positions at which the insulating sheet 460 and the auxiliary plates 430 are provided are not limited to this, and may be between the first secondary winding board 421 or the second secondary winding board 422 and the metal plate 400. In this case, the secondary windings 421c are thermally connected to the metal plate 400 via the insulating sheet 460, or the secondary windings 422c are thermally connected to the metal plate 400 via the insulating sheet 460.

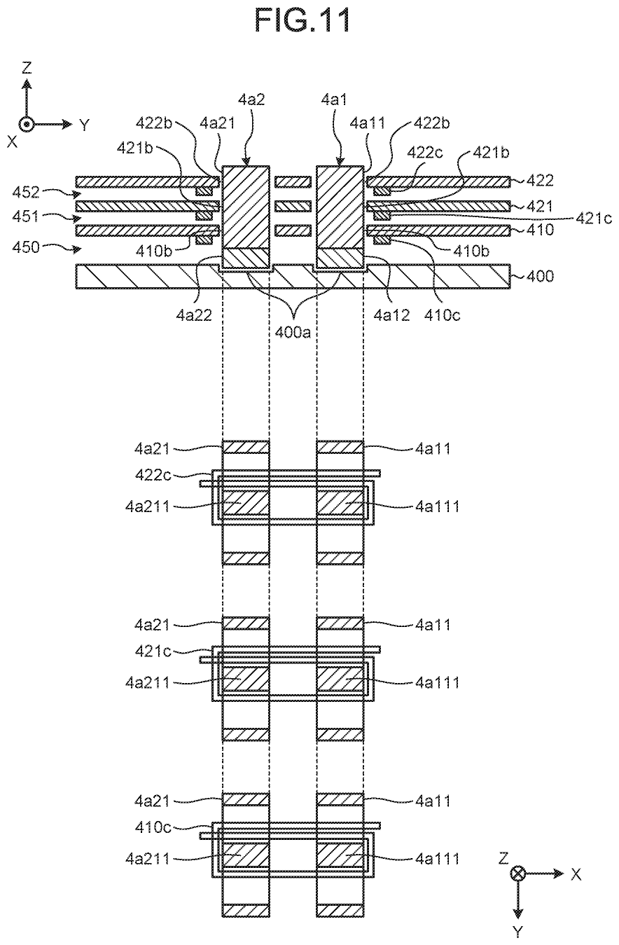

FIG. 11 is a diagram illustrating a modification of the windings illustrated in FIG. 5. In FIG. 5, the primary windings 410c, the secondary windings 421c, and the secondary windings 422c are wound around the center leg 4a111 and the center leg 4a211. The way the primary windings 410c, the secondary windings 421c, and the secondary windings 422c are wound is not limited to the example of FIG. 5. As illustrated in FIG. 11, with the center leg 4a111 and the center leg 4a211 being used as a pair of cores, the primary winding 410c, the secondary winding 421c, and the secondary winding 422c may be wound around the pair of cores.

The configuration described in the above embodiment illustrates an example of the subject matter of the present invention, and can be combined with another known art, and can be partly omitted or changed without departing from the scope of the present invention.

### REFERENCE SIGNS LIST

1 rectifier circuit; 2 capacitor; 3 inverter circuit; 4, 4A planar transformer; 4a transformer; 4a1, 4a2 EI core; 4a11, 4a21 E core; 4a111, 4a211 center leg; 4a12, 4a22 I core; 5, 6 rectifier diode; 7 smoothing reactor; 8 current detector; 10 constant current control unit; 40 EI core group; 100 laser machining apparatus; 110, 110A, 110B laser diode-driving power supply; 120 laser diode; 130 fiber; 140 machining head; 150 lens; 200 AC source; 300 workpiece; 400 metal plate; 400a recessed portion; 410 primary winding board; 410a, 421a, 422a, 440a spacer; 410b, 421b, 422b through hole; 410c primary winding; 421 first secondary winding board; 421c, 422c secondary winding; 421d, 422d output terminal; 422 second secondary winding board; 430 auxiliary plate; 440 pressing spring; 450, 451, 452 gap; 460 insulating sheet; 470, 470a, 472 screw; 471 metal spacer.

1. A planar transformer comprising:
a plurality of EI cores;
a primary winding board provided with primary windings each surrounding a corresponding one of center legs of the EI cores; and
a secondary winding board provided with secondary windings each surrounding the corresponding one of the center legs of the EI cores, wherein
the primary winding board and the secondary winding board are layered in a spaced relation with each other
an air layer is formed between the primary winding board and the secondary winding board, and
the primary windings each surrounding the corresponding one of the center legs of the EI cores are connected in series.

2. A planar transformer comprising:
a plurality of EI cores;
a primary winding board provided with primary windings each surrounding a corresponding one of center legs of the EI cores; and
a secondary winding board provided with secondary windings each surrounding the corresponding one of the center legs of the EI cores, wherein
the secondary windings each surrounding the corresponding one of the center legs of the EI cores are connected in series.

3. The planar transformer according to claim 1, wherein the secondary windings each surrounding the corresponding one of the center legs of the EI cores are connected in parallel.

4. A planar transformer comprising:
a plurality of EI cores;
a primary winding board provided with primary windings each surrounding a corresponding one of center legs of the EI cores; and
a secondary winding board provided with secondary windings each surrounding the corresponding one of the center legs of the EI cores, wherein
the primary winding board and the secondary winding board are layered in a spaced relation with each other, and
an air layer is formed between the primary winding board and the secondary winding board,
wherein the secondary winding board comprises a first secondary winding board and a second secondary winding board,
the secondary windings comprise first secondary windings provided on the first secondary winding board and second secondary windings provided on the second secondary winding board,
the first secondary winding board and the second secondary winding board are layered in a spaced relation with each other,
the first secondary winding board is provided with first output terminals electrically connected to the first secondary windings and second output terminals, and
the second secondary windings provided on the second secondary winding board are electrically connected to the second output terminals via conductive members provided between the first secondary winding board and the second secondary winding board.

5-8. (canceled)

9. A laser diode-driving power supply comprising:
the planar transformer according to claim 4;
a first rectifier diode to rectify a voltage output from the first output terminals;
a second rectifier diode to rectify a voltage output from the second output terminals; and
a laser diode to which a voltage obtained by adding up the voltage rectified by the first rectifier diode and the voltage rectified by the second rectifier diode is applied.

10. A laser diode-driving power supply comprising the planar transformer according to claim 1.

11. A laser machining apparatus comprising the laser diode-driving power supply according to claim 9.

12. A laser diode-driving power supply comprising the planar transformer according to claim 2.

13. A laser diode-driving power supply comprising the planar transformer according to claim 4.

14. A laser machining apparatus comprising the laser diode-driving power supply according to claim 10.

15. A laser machining apparatus comprising the laser diode-driving power supply according to claim 12.

16. A laser machining apparatus comprising the laser diode-driving power supply according to claim 13.
